(19) United States
(12) Patent Application Publication
(10) Pub. No.: US 2025/0118672 A1
(43) Pub. Date: Apr. 10, 2025

(54) SEMICONDUCTOR PACKAGE

(71) Applicant: SAMSUNG ELECTRONICS CO., LTD., Suwon-si (KR)

(72) Inventors: Sang Sub Song, Suwon-si (KR); Eunkyeong Park, Suwon-si (KR); Seokbeom Yong, Suwon-si (KR)

(21) Appl. No.: 18/759,447

(22) Filed: Jun. 28, 2024

(30) Foreign Application Priority Data
Oct. 10, 2023 (KR) 10-2023-0134370

(51) Int. Cl. H01L 23/528; H01L 23/00; H01L 23/14; H01L 23/498; H01L 23/522; H01L 25/18; H10B 80/00

(52) U.S. Cl. CPC H01L 23/5286; H01L 23/14; H01L 23/49833; H01L 23/5226; H01L 24/16; H01L 25/18; H01L 2224/16225; H01L 2924/1436; H10B 80/00

(57) ABSTRACT

A semiconductor packaging structure is provided including first through third routing layers. Each of the first through third routing layers includes a first through a third plurality of signal wires and a first through a third plurality of ground wires arranged alternately in a first horizontal direction. A plurality of vias connect the first to third ground wires to each other. The first to third signal wires and the first to third ground wires extend in a second horizontal direction intersecting the first horizontal direction. Each signal wire among the first to third signal wires is separated from any other signal wires. The first to third pluralities of signal wires overlap each other, and the first to third pluralities of ground wires overlap each other.

### CROSS-REFERENCE TO RELATED APPLICATION

This application claims priority to and the benefit of Korean Patent Application No. 10-2023-0134370, filed in the Korean Intellectual Property Office on Oct. 10, 2023, the entire contents of which are incorporated herein by reference.

### BACKGROUND

An interconnection structure connects semiconductor chips embedded in the electronic products. For example, the interconnect structure includes signal wires, ground wires, and a dielectric surrounding the signal wires and the ground wires, and is configured to exchange signals with semiconductor chips through the signal wires and the ground wires.

### SUMMARY

The signal wires and the ground wires within an interconnect structure may be disposed such that signal wires and ground wires are arranged alternately within each routing layer, the signal wires are arranged to overlap vertically within the routing layers, the ground wires are arranged to overlap vertically within the routing layers, and the ground wires are connected to each other by vias.

The signal wires and ground wires within the interconnect structure may be arranged such that a gap between the signal wire and the ground wire within each of the routing layers is smaller than a height of the signal wire and the gap between the signal wire and the ground wire within each of the routing layers is smaller than a height of a dielectric between the signal wires in the vertical direction.

An implementation disclosed herein provides a semiconductor structure including: a first routing layer configured to include a plurality of first signal wires and a plurality of first ground wires arranged alternately in a first horizontal direction; a second routing layer configured to include a plurality of second signal wires and a plurality of second ground wires alternately arranged in the first horizontal direction, and disposed on the first routing layer; a third routing layer configured to include a plurality of third signal wires and a plurality of third ground wires alternately arranged in the first horizontal direction, and disposed on the second routing layer; and a plurality of vias configured to connect the first to third ground wires to each other, wherein the first to third signal wires and the first to third ground wires extend in a second horizontal direction intersecting the first horizontal direction, each signal wire among the first to third signal wires is separated from remaining signal wires, the first to third signal wires overlap each other, and the first to third ground wires overlap each other.

An implementation disclosed herein provides a semiconductor structure including: a first routing layer configured to include a plurality of first signal wires and a plurality of first ground wires arranged alternately in a first horizontal direction; a first connection layer configured to include a plurality of first vias connected to the first ground wires and disposed on the first routing layer; a second routing layer configured to include a plurality of second signal wires and a plurality of second ground wires alternately arranged in the first horizontal direction, and disposed on the first connection layer, wherein the second ground wires are connected to the first vias; a second connection layer configured to include a plurality of second vias connected to the second ground wires and disposed on the second routing layer; a third routing layer configured to include a plurality of third signal wires and a plurality of third ground wires alternately arranged in the first horizontal direction, and disposed on the second connection layer, wherein the third ground wires are connected to the second vias; and a dielectric configured to surround the first to third signal wires, the first to third ground wires, and the first to second vias, wherein the first to third signal wires and the first to third ground wires extend in a second horizontal direction intersecting the first horizontal direction, each signal wire among the first to third signal wires is separated from remaining signal wires, the first to third signal wires overlap each other, and the first to third ground wires overlap each other.

An implementation disclosed herein provides a semiconductor package including: a substrate; an interconnection structure on the substrate; a semiconductor die on the interconnection structure; and a semiconductor stacking structure on the interconnection structure, wherein the interconnection structure includes: a first routing layer configured to include a plurality of first signal wires and a plurality of first ground wires arranged alternately in a first horizontal direction; a second routing layer configured to include a plurality of second signal wires and a plurality of second ground wires alternately arranged in the first horizontal direction, and disposed on the first routing layer; a third routing layer configured to include a plurality of third signal wires and a plurality of third ground wires alternately arranged in the first horizontal direction, and disposed on the second routing layer; and a plurality of vias configured to connect the first to third ground wires to each other, wherein the first to third signal wires and the first to third ground wires extend in a second horizontal direction intersecting the first horizontal direction, each signal wire among the first to third signal wires is separated from remaining signal wires, the first to third signal wires overlap each other, and the first to third ground wires overlap each other.

The signal wires and the ground wires within an interconnect structure may be disposed such that signal wires and ground wires are arranged alternately within each routing layer, the signal wires are arranged to overlap vertically within the routing layers, the ground wires are arranged to overlap vertically within the routing layers, and the ground wires are connected to each other by vias.

The signal wires and ground wires within the interconnect structure may be arranged such that a gap between the signal wire and the ground wire within each of the routing layers is smaller than a height of the signal wire and the gap between the signal wire and the ground wire within each of the routing layers is smaller than a height of a dielectric between the signal wires in the vertical direction.

Accordingly, by the disposition of the signal wires and the ground wires within the interconnect structure, the I/O of more semiconductor chips may be connected to the interconnection structure without deteriorating signal integrity (SI), and crosstalk occurring between neighboring signal wires may be suppressed.

### BRIEF DESCRIPTION OF THE DRAWINGS

FIG. 1 illustrates a cross-sectional view showing an example semiconductor package.

FIG. 2 illustrates a cross-sectional view showing an example semiconductor package.

FIG. 3 illustrates a cross-sectional view showing disposition of signal wires and a ground layer in a conventional interconnection structure.

FIG. 4 illustrates a top plan view showing disposition of conventional signal wires and a ground layer.

FIG. 5 illustrates a cross-sectional view showing disposition of signal wires and ground wires in an example interconnection structure.

FIG. 6 illustrates a cross-sectional view showing disposition of signal wires and ground wires in an example interconnection structure.

FIG. 7 illustrates a top plan view showing disposition of signal wires and ground wires in an interconnection structure.

FIG. 8 illustrates a graph showing a relationship between a thickness of a dielectric material and signal integrity (SI).

### DETAILED DESCRIPTION

The present disclosure will be described more fully hereinafter with reference to the accompanying drawings, in which implementations of the disclosure are shown. As those skilled in the art would realize, the described implementations may be modified in various different ways, all without departing from the spirit or scope of the present disclosure.

To clearly describe the present disclosure, parts that are irrelevant to the description in the drawings are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

For high-performance electronic products, an interconnection structure that connects semiconductor chips embedded in the electronic products is desired to have improved functionality. For example, the interconnect structure includes signal wires, ground wires, and a dielectric surrounding the signal wires and the ground wires, and is configured to exchange signals with semiconductor chips through the signal wires and the ground wires.

When a signal transmitted from the interconnection structure has a low frequency, the signal transmission is not affected by the design arrangement of signal and ground wires (other than a design that significantly reduces a path length of signal wires) and the dielectric constant of a dielectric in the interconnect structure. However, when a signal transmitted from the interconnection structure has a high frequency, the signal transmission is under the complex effect of the design arrangement of signal and ground wires and the dielectric constant of a dielectric within the interconnection structure. In order to transmit signals at a high speed, it is desired to secure a wide bandwidth. Such high frequency conditions can be satisfied by a micro-strip line structure and a strip line structure included within the interconnection structure.

The micro-strip line structure includes a ground layer formed by one metal plate over an entire lowermost layer; a dielectric disposed on a ground layer and having a defined thickness and permittivity; and a signal wire disposed on the dielectric. The strip line structure includes a signal wiring layer; and ground layers disposed at an upper portion and a lower portion of the signal wiring layer.

However, in the micro-strip line structure and the strip line structure, when the thickness of the dielectric in a horizontal direction between signal wires in a signal wiring layer is constant, the thickness of the dielectric in a horizontal direction between signal wires in the signal wiring layer becomes relatively thinner than the thickness of the dielectric in the vertical direction between the signal wiring layer and the ground layer, if the thickness of the dielectric in a vertical direction between the signal wiring layer and the ground layer increases. As a result, cross talk between relatively thin signal wires becomes severe, and signal integrity (SI) deteriorates. A design margin for disposition between signal wires and the ground layer is reduced, and dielectric materials with thicker interlayer thicknesses compared to silicon materials become difficult to use in the interconnection structure.

Furthermore, the micro-strip line structure and the strip line structure are formed by alternately stacking ground layers and signal wiring layers, and thus all the layers may not be used as signal layers. Accordingly, to increase the number of I/O in the micro-strip line structure and the strip line structure, a thickness of wires in the horizontal direction and a gap between the wires needs to be reduced. When the thickness of the signal wires in the horizontal direction and the gap between the signal wires are reduced, crosstalk between the signal wires becomes severe, and the signal integrity (SI) deteriorates.

Hereinafter, a semiconductor package of an implementation will be described with reference to drawings.

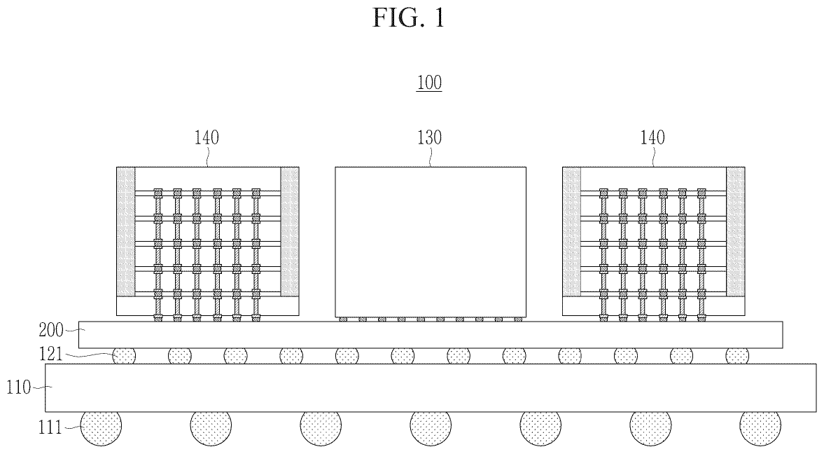

FIG. 1 illustrates a cross-sectional view showing an example semiconductor 100.

Referring to FIG. 1, the semiconductor package 100 includes a substrate 110, an interconnection structure 200, a semiconductor die 130, and a semiconductor stacking structure 140. In an implementation, the semiconductor package 100 may include a 2.5D semiconductor package.

The Substrate 110 is disposed on a lower surface of the interconnect structure 200. In an implementation, the substrate 110 may include an ajinomoto build-up film (ABF) substrate. In an implementation, the substrate 110 may include a printed circuit board (PCB). The substrate 110 may include an insulating layer and wiring layers and vias within the insulating layer. External connection members 111 are disposed on a lower surface of the substrate 110. The external connection member 111 electrically connects the substrate 110 to an external device. In an implementation, the external connection member 111 may include a solder ball or conductive bump.

The interconnection structure 200 is disposed between the substrate 110 and the semiconductor die 130, and between the substrate 110 and the semiconductor stacking structure 140. The interconnection structure 200 electrically connects the semiconductor die 130 to the substrate 110 in a vertical direction, and electrically connects the semiconductor stacking structure 140 to the substrate 110 in the vertical direction. The interconnection structure 200 electrically connects the semiconductor die 130 and the semiconductor stacking structure 140 in the horizontal direction. The interconnection structure 200 functions as an intermediate medium including an intermediate-level wire connecting the semiconductor die 130 with I/O of a fine pitch and the semiconductor stacking structure 140 with I/O of a fine pitch to I/O of a normal pitch. In an implementation, the interconnection structure 200 may include a silicon interposer. The interconnection structure 200 is electrically connected to the substrate by connection members 121.

The semiconductor die 130 is disposed on the interconnection structure 200. The semiconductor die 130 is electrically connected to the interconnection structure 200 through a connection member. The semiconductor die 130 is electrically connected to the semiconductor stacking structure 140 and the substrate 110 through the interconnection structure 200. In an implementation, the semiconductor chip 130 may include a system on chip (SOC). In an implementation, the semiconductor die 130 may include at least one of a central processing unit (CPU) or a graphics processing unit (GPU).

The semiconductor stacking structure 140 is disposed on the interconnection structure 200. A number of the semiconductor stacking structure 140 may be one or more. The semiconductor stacking structure 140 is electrically connected to the interconnection structure 200 through a connection member. The semiconductor stacking structure 140 is electrically connected to the semiconductor die 130 and the substrate 110 through the interconnection structure 200. In an implementation, the semiconductor stacking structure 140 may include a high bandwidth memory (HBM).

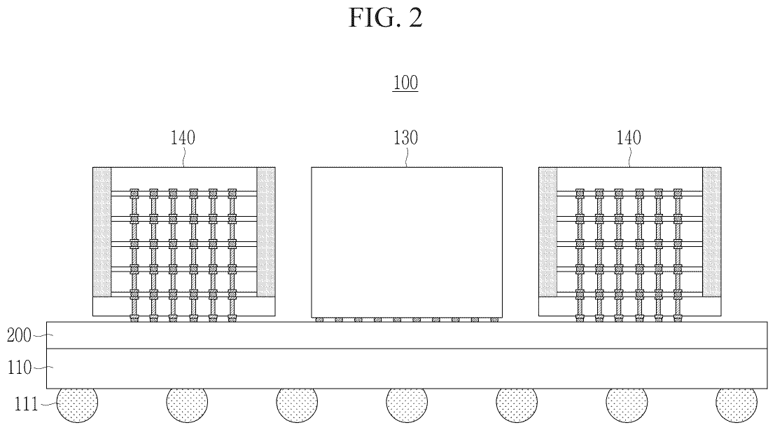

FIG. 2 illustrates a cross-sectional view showing the semiconductor package 100.

Referring to FIG. 2, the semiconductor package 100 includes a substrate 110, an interconnection structure 200, a semiconductor die 130, and a semiconductor stacking structure 140. In an implementation, the semiconductor package 100 may include a 2.1D semiconductor package.

The substrate 110 may include a glass or plastic core. A lower surface of the interconnection structure 200 is in direct contact with the upper surface of the substrate 110 without a connection member. The interconnection structure 200 is formed by directly implementing a fine pattern on the substrate 110. In an implementation, the interconnection structure 200 may include a redistribution layer (RDL) structure.

In addition to the above-mentioned description, for contents of the substrate 110, the interconnection structure 200, the semiconductor die 130, and the semiconductor stacking structure 140, contents of the substrate 110, the interconnection structure 200, the semiconductor die 130, and the semiconductor stacking structure 140 described with respect to FIG. 1 may be applied.

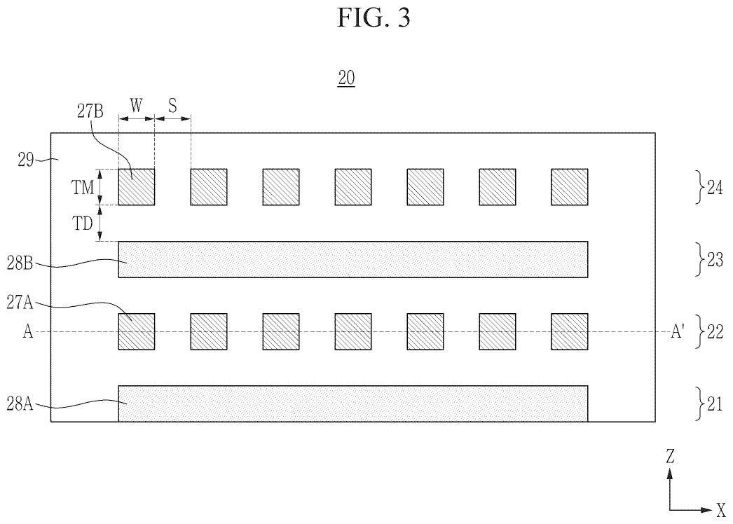

FIG. 3 illustrates a cross-sectional view showing disposition of signal wires 27 and a ground layer 28 in a conventional interconnection structure 20.

Referring to FIG. 3, the conventional interconnection structure 20 includes a strip line structure. The strip line structure includes a first ground layer 28A, fifth signal wires 27A, a second ground layer 28B, sixth signal wires 27B, and a dielectric 29.

The first ground layer 28A is positioned within the first routing layer 21. The first ground layer 28A is positioned at a lowermost portion of the strip line structure. The first ground layer 28A is formed of a mesh-shaped conductive member. The first ground layer 28A extends in the direction X (first horizontal direction) and the direction Y (second horizontal direction).

The fifth signal wires 27A are positioned within the second routing layer 22. The fifth signal wires 27A are positioned on the first ground layer 28A. The fifth signal wires 27A are spaced apart from the first ground layer 28A with a pitch TD. The dielectric 29 is positioned between the fifth signal wires 27A and the first ground layer 28A. The fifth signal wires 27A are not electrically connected to the first ground layer 28A but are separated from the first ground layer 28A. The fifth signal wires 27A are not electrically connected to each other and are separated. The fifth signal wires 27A have a width W in the direction X. The fifth signal wire 27A has a height TM in the direction Z (the vertical direction). The fifth signal wires 27A each are spaced apart from the neighboring fifth signal wire 27A in the direction X with a pitch S.

The second ground layer 28B is positioned within the third routing layer 23. The second ground layer 28B is positioned on the fifth signal wires 27A. The second ground layer 28B is spaced apart from the fifth signal wires 27A by a pitch TD. The dielectric 29 is positioned between the second ground layer 28B and the fifth signal wires 27A. The second ground layer 28B is not electrically connected to the fifth signal wires 27A but is separated therefrom. The second ground layer 28B is formed of a mesh-shaped conductive member. The second ground layer 28B extends in the direction X and the direction Y.

The sixth signal wires 27B are positioned within the fourth routing layer 24. The sixth signal wires 27B are positioned at an uppermost portion in the strip line structure. The sixth signal wires 27B are positioned on the second ground layer 28B. The sixth signal wires 27B are spaced apart from the second ground layer 28B with a pitch TD. The dielectric 29 is disposed between the sixth signal wires 27B and the second ground layer 28B. The sixth signal wires 27B are not electrically connected to the second ground layer 28B but are separated therefrom. The sixth signal wires 27B are not electrically connected to each other and are separated. The sixth signal wire 27B has the width W in the direction X. The sixth signal wire 27B has the height TM in the direction Z. The sixth signal wires 27B each are spaced apart from the neighboring fifth signal wire 27B in the direction X with the pitch S.

The dielectric 29 surrounds and insulates the first ground layer 28A, the fifth signal wires 27A, the second ground layer 28B, and the sixth signal wires 27B. In an implementation, the dielectric 29 may include silicon or a silicon oxide.

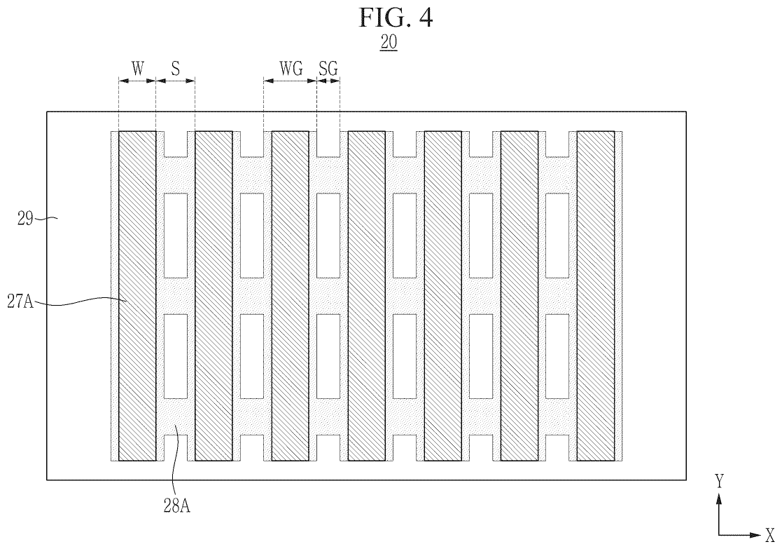

FIG. 4 illustrates a top plan view showing the disposition of the conventional fifth signal wires 27A and the first ground layer 28A. FIG. 4 illustrates a top plan view of the interconnection structure 20 of FIG. 3 taken along a cross section A-A′.

Referring to FIG. 4, the conventional interconnection structure 20 includes a strip line structure. The strip line structure includes the fifth signal wires 27A in the second routing layer 22 and the first ground layer 28A below fifth signal wires 27A.

The fifth signal wires 27A are positioned on the first ground layer 28A. The fifth signal wires 27A extend in the direction Y. In an implementation, the fifth signal wires 27A include an elongated shape. The fifth signal wires 27A are not electrically connected to each other and are separated in the direction X. The fifth signal wires 27A have a width W in the direction X. The fifth signal wires 27A each are spaced apart from the neighboring fifth signal wire 27A in the direction X with a pitch S.

The first ground layer 28A is disposed below the fifth signal wires 27A. The first ground layer 28A is spaced apart from the fifth signal wires 27A by the pitch TD. The first ground layer 28A includes a mesh shape. The first ground layer 28A includes a portion extending in the direction X and a portion extending in the direction Y. The portion of the first ground layer 28A extending in the direction Y has a width WG in the direction X. The portion extending in the direction Y of the first ground layer 28A is spaced apart from the adjacent portion extending in the direction Y with a pitch SG.

As high performance and high integration are required in the semiconductor technology field, semiconductor chips may include a greater number of I/Os, and the interconnection structure 20 may be manufactured such that it may be connected to semiconductor chips with a larger number of I/Os. However, the first ground layer 28A is disposed in the first routing layer 21 of the conventional interconnection structure 20, and the second ground layer 28B is disposed in the third routing layer 23, and thus the first routing layer 21 and the third routing layer 23 of the conventional interconnect structure 20 may not include signal wires. Accordingly, in order to connect signal wires to a semiconductor chip with a greater number of I/Os, space may be secured to incorporate a greater number of signal wires by reducing the width W of the fifth signal wires 27A in the second routing layer 22 and the sixth signal wires 27B in the fourth routing layer 24 in the direction X, and reducing the pitch S between the respective fifth signal wires 27A and between the respectively sixth signal wires 27B. However, if the width W and the distance S are reduced, cross talk between signal wires becomes severe and signal integrity (SI) deteriorates.

Furthermore, the dielectric of the redistribution layer structure (e.g., a photosensitive dielectric (PID)) is made of a material that is more difficult to implement a fine pattern than the dielectric of the silicon interposer (e.g., a silicon oxide). Therefore, when attempting to connect a substrate and semiconductor chips using a relatively inexpensive redistribution structure without using a silicon interposer, a thickness TD of the dielectric between routing layers inevitably increases. However, as the thickness TD of the dielectric between routing layers increases, the pitch S between signal wires becomes smaller than the pitch TD between signal wires and ground wires. Therefore, cross talk between signal wires becomes severe, and signal integrity SI deteriorates.

As a result of testing to support this hypothesis, in the conventional interconnection structure 20, eye opening was lowered from 70% to 2% when the height TM of the fifth and sixth signal wires 27 was increased from 1 μm to 3 μm, and the pitch TD of the dielectric 290 between the first and second ground layers 28 and the fifth and sixth signal wires 27 was also increased from 1 μm to 3 μm.

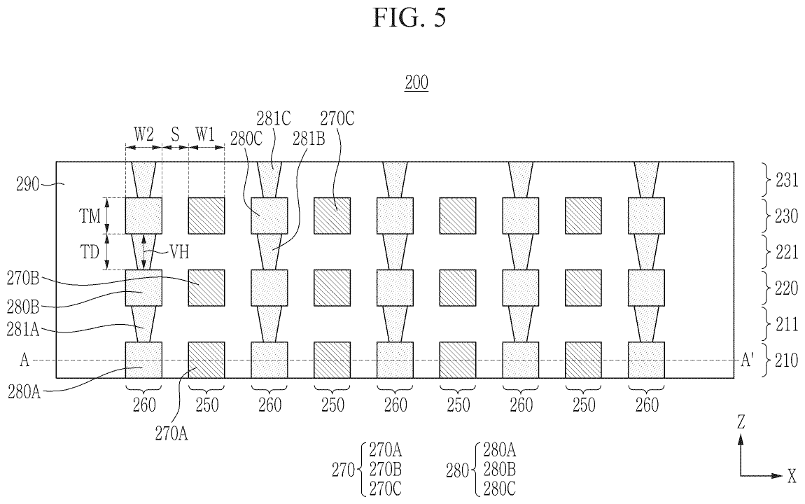

FIG. 5 illustrates a cross-sectional view showing a disposition of signal wires 270 and ground wires 280 in the interconnection structure 200 according to an implementation.

Referring to FIG. 5, the interconnection structure 200 includes a vertical strip line structure. The vertical strip line structure includes first signal wires 270A, second signal wires 270B, third signal wires 270C, first ground wires 280A, second ground wires 280B, third ground wires 280C, a first via 281A, a second via 281B, a third via 281C, and a dielectric 290.

The first signal wires 270A and the first ground wires 280A are positioned within the first routing layer 210. The first signal wires 270A and the first ground wires 280A are positioned at a lowermost portion in the vertical strip line structure. The first signal wires 270A and the first ground wires 280A are arranged alternately in the direction X. The first signal wires 270A and the first ground wires 280A have a height TM in the direction Z. The first signal wires 270A each are spaced apart from the neighboring first ground wire 280A in the direction X with a pitch S. The first signal wires 270A and the first ground wires 280A are not electrically connected to each other and are separated.

The first signal wires 270A each have a width W1 in the direction X. The first signal wires 270A are not electrically connected to each other and are separated. Each of the first signal wires 270A is electrically connected to the substrate 110. Each of the first signal wires 270A is electrically connected to at least one of the semiconductor die 130 or the semiconductor stacking structure 140.

The first ground wires 280A each have a width W2 in the direction X. Each of the first ground wires 280A is disposed below a first via 281A and is electrically connected to the first via 281A.

The first vias 281A are positioned within a first connection layer 211. The first vias 281A are disposed between the second ground wires 280B and the first ground wires 280A. The first via 281A electrically connects the second ground wire 280B to the first ground wire 280A. The first connection layer 211 has a height TD in the direction Z. The first vias 281A have a height VH in the direction Z. The height VH is equal to the height TD. In an implementation, the first vias 281A may include a polygonal or a circular shape in a horizontal cross-section.

The second signal wires 270B and the second ground wires 280B are positioned within the second routing layer 220. The second signal wires 270B and the second ground wires 280B are arranged alternately in the direction X. The second signal wires 270B and the second ground wires 280B have the height TM in the direction Z. The second signal wires 270B each are spaced apart from the neighboring second ground wire 280B in the direction X with the pitch S. The second signal wires 270B and the second ground wires 280B are not electrically connected to each other and are separated.

The second signal wires 270B each have a width W1 in the direction X. The second signal wire 270B is spaced apart from the neighboring first signal wire 270A in the direction Z at a pitch (height: TD). The second signal wires 270B are not electrically connected to each other and are separated. each of the second signal wires 270B each is not electrically connected to the neighboring first signal wire 270A in the direction Z but is separated from the neighboring first signal wire 270A. Each of the second signal wires 270B is electrically connected to at least one of the semiconductor die 130 or the semiconductor stacking structure 140.

The second ground wires 280B each have a width W2 in the direction X. Each of the second ground wires 280B is disposed between the first via 281A and the second via 281B. Each of the second ground wires 280B electrically connects the second via 281B to the first via 281A.

The second vias 281B are positioned within the second connection layer 221. The second vias 281B are disposed between the third ground wires 280C and the second ground wires 280B. The second via 281B electrically connects the third ground wire 280C to the second ground wire 280B. The second connection layer 221 has a height TD in the direction Z. The second vias 281B have a height VH in the direction Z. The height VH is equal to the height TD. In an implementation, the second vias 281B may include a polygonal or circular shape in a horizontal cross-section.

The third signal wires 270C and the third ground wires 280C are positioned within the third routing layer 230. The third signal wires 270C and the third ground wires 280C are arranged alternately in the direction X. The first signal wires 270C and the first ground wires 280C have a height TM in the direction Z. The third signal wires 270C each are spaced apart from the neighboring third ground wire 280C in the direction X with the pitch S. The third signal wires 270C and the third ground wires 280C are not electrically connected to each other and are separated.

The third signal wires 270C each have a width W1 in the direction X. The third signal wire 270C is spaced apart from the neighboring second signal wire 270B in the direction Z at a pitch (height: TD). The third signal wires 270C are not electrically connected to each other and are separated. Each of the third signal wires 270C is not electrically connected to the neighboring second signal wire 270B and the first signal wire 270A in the direction Z but is separated therefrom. Each of the third signal wires 270C is electrically connected to at least one of the semiconductor die 130 or the semiconductor stacking structure 140.

The third ground wires 280C each have a width W2 in the direction X. Each of the third ground wires 280C is disposed between the second via 281B and the third via 281C. Each of the third ground wires 280C is electrically connected to the third via 281C and the second via 281B.

The third vias 281C are positioned within the third connection layer 231. The third vias 281C are disposed on the third ground wires 280C. The third via 281C is electrically connected to the third ground wire 280C. The third connection layer 231 has a height TD in the direction Z. The third vias 281C have a height VH in the direction Z. The height VH is equal to the height TD. In an implementation, the third vias 281C may include a polygonal or circular shape in a horizontal cross-section.

The first signal wires 270A, the second signal wires 270B, and the third signal wires 270C have a first vertical structure 250 and are arranged to overlap each other. The first ground wires 280A, the second ground wires 280B, and the third ground wires 280C have a second vertical structure 260 and are disposed to overlap each other. Among the first signal wires 270A, the second signal wires 270B, and the third signal wires 270C, each signal wire routes a signal different from signals routed by the remaining signal wires.

The dielectric 290 surrounds and insulates the first signal wires 270A, the second signal wires 270B, the third signal wires 270C, the first ground wires 280A, the second ground wires 280B, the third ground wires 280C, the first vias 281A, the second vias 281B, and the third vias 281C. In an implementation where the interconnection structure 200 is a silicon interposer, the dielectric 290 may include silicon or a silicon oxide. In an implementation, where the interconnection structure 200 is a redistribution layer structure, dielectric 290 may include a photosensitive dielectric (PID).

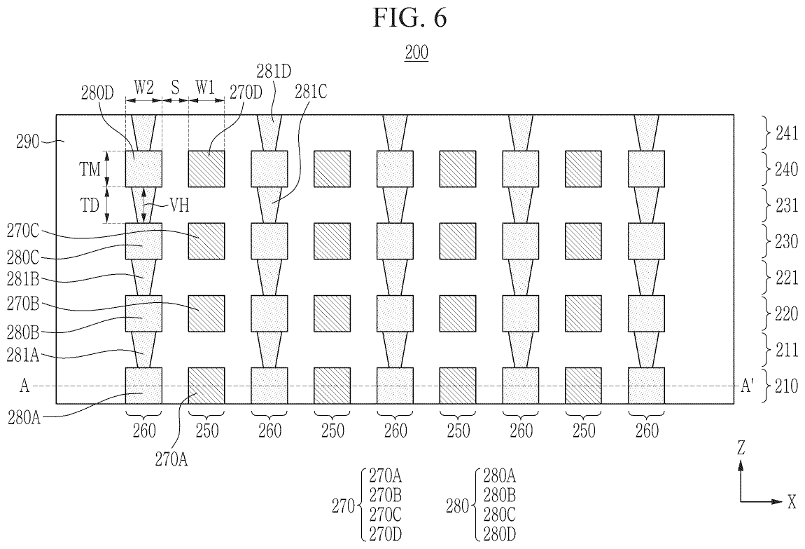

FIG. 6 illustrates a cross-sectional view showing disposition of signal wires 270 and ground wires 280 in the interconnection structure 200 according to another implementation.

Referring to FIG. 6, the interconnection structure 200 includes a vertical strip line structure. The vertical strip line structure includes first signal wires 270A, second signal wires 270B, third signal wires 270C, fourth signal wires 270D, first ground wires 280A, second ground wires 280B, third ground wires 280C, fourth ground wires 280D, first vias 281A, second vias 281B, third vias 281C, fourth vias 281D, and a dielectric 290.

Contents described in FIG. 5 with respect to the first signal wires 270A, the second signal wires 270B, the third signal wires 270C, the first ground wires 280A, the second ground wires 280B, the third ground wires 280C, the first vias 281A, the second vias 281B, and the dielectric 290 may be equally applied to FIG. 6.

The third vias 281C are positioned within the third connection layer 231. The third vias 281C are disposed between the fourth ground wires 280D and the third ground wires 280C. The third via 281C electrically connects the fourth ground wire 280D to the third ground wire 280C. The third connection layer 231 has a height TD in the direction Z. The third vias 281C have a height VH in the direction Z. The height VH is equal to the height TD. In an implementation, the third vias 281C may include a polygonal or circular shape in a horizontal cross-section.

The fourth signal wires 270D and the fourth ground wires 280D are positioned within the fourth routing layer 240. The fourth signal wires 270D and the fourth ground wires 280D are arranged alternately in the direction X. The first signal wires 270D and the fourth ground wires 280D have a height TM in the direction Z. The fourth signal wires 270D each are spaced apart from the neighboring fourth ground wire 280D in the direction X with the pitch S. The fourth signal wires 270D and the fourth ground wires 280D are not electrically connected to each other and are separated.

The fourth signal wires 270D each have a width W1 in the direction X. The fourth signal wire 270D is spaced apart from the neighboring third signal wire 270C in the direction Z at a pitch (height: TD). The fourth signal wires 270D are not electrically connected to each other and are separated. Each of the fourth signal wires 270D is not electrically connected to the third signal wire 270C, the second signal wire 270B and the first signal wire 270A that are adjacent in direction Z but is separated therefrom. Each of the fourth signal wires 270D is electrically connected to at least one of the semiconductor die 130 or the semiconductor stacking structure 140.

The fourth ground wires 280D each have a width W2 in the direction X. Each of the fourth ground wires 280D is disposed between the third via 281C and the fourth via 281D. Each of the fourth ground wires 280D is electrically connected to the fourth via 281D and the third via 281C.

The fourth vias 281D are positioned within the fourth connection layer 241. The fourth vias 281D are disposed on the fourth ground wires 280D and are electrically connected to the fourth ground wires 280D. In an implementation, the fourth vias 281D may include a polygonal or circular shape in a horizontal cross-section.

The first signal wires 270A, the second signal wires 270B, the third signal wires 270C, and the fourth signal wires 270D have a first vertical structure 250 and are arranged to overlap each other. The first ground wires 280A, the second ground wires 280B, the third ground wires 280C, and the fourth ground wires 280D have a second vertical structure 260 and are arranged to overlap each other. Among the first signal wires 270A, the second signal wires 270B, the third signal wires 270C, and the fourth signal wires 270D, each signal wire routes a signal different from signals routed by the remaining signal wires.

The dielectric 290 surrounds and insulates the first signal wires 270A, the second signal wires 270B, the third signal wires 270C, the fourth signal wires 270D, the first ground wires 280A, the second ground wires 280B, the third ground wires 280C, the fourth ground wires 280D, the first vias 281A, the second vias 281B, the third vias 281C, and the fourth vias 281D. In an implementation where the interconnection structure 200 is a silicon interposer, the dielectric 290 may include silicon or a silicon oxide. In an implementation, where the interconnection structure 200 is a redistribution layer structure, dielectric 290 may include a photosensitive dielectric (PID).

According to the implementation of FIG. 5 including the first routing layer 210 to the third routing layer 230, a size of the interconnection structure 200 may be reduced. According to the implementation of FIG. 6 including the first routing layer 210 to the fourth routing layer 240, it may be possible to connect the signal wires 270 to more I/Os.

In the implementation of FIG. 5, the interconnection structure 200 is illustrated to include three routing layers, and in the implementation of FIG. 6, the interconnection structure 200 is illustrated to include four routing layers, but the number of routing layers is not limited thereto. In addition to the first routing layer 210 to the third routing layer 230 of FIG. 5, the interconnection structure 200 according to the present disclosure may further include a fourth routing layer to an (N+4)^{th} routing layer. In this case, N is a natural number greater than 1. The fourth to (N+4)^{th} routing layers each include a plurality of signal wires and a plurality of ground wires arranged alternately in the first horizontal direction (the direction X). Regarding characteristics of the signal wires and the ground wires, the contents described with respect to FIG. 5 may be equally applied.

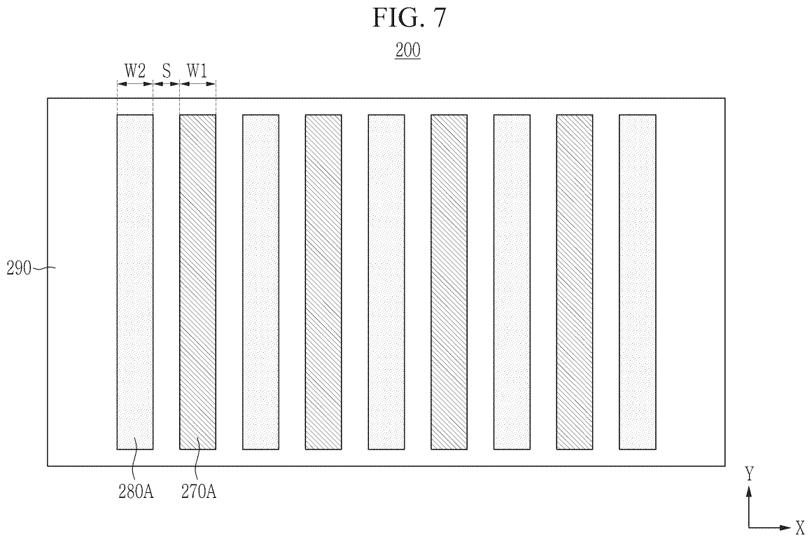

FIG. 7 illustrates a top plan view showing a disposition of first signal wires 270A and first ground wires 280A in the interconnection structure 200. FIG. 7 illustrates a top plan view of the structure 200 of FIG. 5 and FIG. 6 taken along a cross section A-A′.

Referring to FIG. 7, the interconnection structure 200 includes a vertical strip line structure. The vertical strip line structure includes the first signal wires 270A and the first ground wires 280A within the first routing layer 210.

The first signal wires 270A extend in the direction Y. The first signal wires 270A have an elongated shape. The first signal wires 270A are not electrically connected to each other and are separated in the direction X. The first signal wires 270A have a width W1 in the direction X. The first signal wires 270A each are spaced apart from the neighboring first ground wire 280A in the direction X with a pitch S.

The first ground wires 280A extend in the direction Y. The first ground wires 280A have an elongated shape. The first ground wires 280A have a width W2 in the direction X.

Referring to FIG. 5 to FIG. 7, the pitch S between the signal wire 270 and the ground wire 280 adjacent to the signal wire 270 in the direction X is smaller than the pitch TD between the upper signal wire and the lower signal wire in a vertical structure. As a result, a signal from any signal wire 270 is directed toward the ground wire 280, which is closer in distance, rather than toward the neighboring signal wire 270, which is relatively distant, so cross talk may be reduced and signal integrity (SI) may be improved.

The pitch S between the signal wire 270 and the ground wire 280 adjacent to the signal wire 270 in the direction X is smaller than the height TM of the signal wire 270 in the direction Z and the height TM of the ground wire 280 in the direction Z. Accordingly, resistance may be reduced by designing the height TM of the signal wire 270 in the direction Z and the height TM of the ground wire 280 in the direction Z to be as high as possible. Furthermore, by reducing the pitch S between the signal wire 270 and the neighboring ground wire 280 in the direction X, cross talk may be reduced between the signal wires, and signal integrity (SI) may be improved. Furthermore, by reducing the pitch S between the signal wire 270 and the neighboring ground wire 280 in the direction X, it may become possible to dispose more signal wires 270 and to connect the signal wires 270 to more I/Os.

According to the present disclosure, signal wires may be disposed within all routing layers, and thus signal integrity (SI) characteristics required for high-performance semiconductor chips may be secured even without further increasing the number of routing layers.

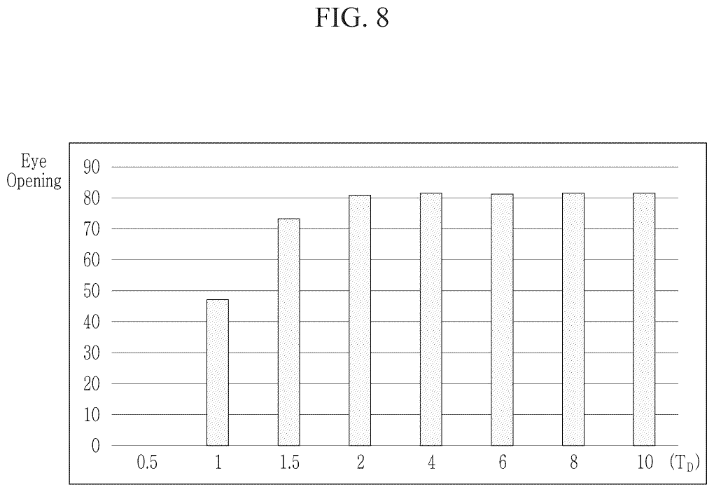

FIG. 8 illustrates a graph showing a relationship between a thickness of a dielectric material and signal integrity (SI).

According to the present disclosure, in a vertical structure, the pitch TD between the upper signal wire and the lower signal wire may be implemented to be larger than the pitch S between the signal wire 270 and the ground wire 280 adjacent to the signal wire 270 in the direction X, and thus although a dielectric with a relatively thick distance between wires is used, it may be possible to secure signal integrity (SI) characteristics required for high-performance semiconductor chips. Test results supporting these characteristics are illustrated in FIG. 8. Referring to FIG. 8, in the vertical structure, it was found that although the pitch TD between the upper and lower signal wires increases from about 2 μm to about 10 μm, an eye opening value could be maintained above 80. In an implementation, the pitch (TD) between the upper and lower signal wires may be about 2 μm to about 10 μm. Accordingly, the interconnection structure 200 may be manufactured using a redistribution layer structure using a photosensitive dielectric (PID), in which it is relatively difficult to implement a fine pattern compared to a silicon material, as a dielectric material.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with what is presently considered to be practical implementations, it is to be understood that the invention is not limited to the disclosed implementations, but, on the contrary, is intended to cover various modifications and equivalent arrangements included within the spirit and scope of the appended claims.

What is claimed is:

1. A semiconductor structure comprising:
a first routing layer including a plurality of first signal wires and a plurality of first ground wires that are arranged alternately in a first horizontal direction;
a second routing layer including a plurality of second signal wires and a plurality of second ground wires that are alternately arranged in the first horizontal direction and disposed on the first routing layer;
a third routing layer including a plurality of third signal wires and a plurality of third ground wires that are alternately arranged in the first horizontal direction and disposed on the second routing layer; and
a plurality of vias connecting the plurality of first ground wires, the plurality of second ground wires, and the plurality of third ground wires to each other,
wherein the plurality of first signal wires, the plurality of second signal wires, the plurality of third signal wires, the plurality of first ground wires, the plurality of second ground wires, and the plurality of third ground wires extend in a second horizontal direction intersecting the first horizontal direction,
wherein each signal wire among the plurality of first signal wires, the plurality of second signal wires, and the plurality of third signal wires is separated from remaining signal wires,
wherein the plurality of first signal wires, the plurality of second signal wires, and the plurality of third signal wires overlap each other, and
wherein the plurality of first ground wires, the plurality of second ground wires, and the plurality of third ground wires overlap each other.

2. The semiconductor structure of claim 1, wherein
each signal wire among the plurality of first signal wires, the plurality of second signal wires, and the plurality of third signal wires is configured to route a signal different from signals routed by the remaining signal wires.

3. The semiconductor structure of claim 1, wherein
a pitch between each signal wire among the plurality of first signal wires, the plurality of second signal wires, and the plurality of third signal wires and a ground wire adjacent to each signal wire in the first horizontal direction is smaller than a height of each signal wire.

4. The semiconductor structure of claim 1, wherein
a pitch between each signal wire among the plurality of first signal wires, the plurality of second signal wires, and the plurality of third signal wires and a ground wire adjacent to each signal wire in the first horizontal direction is smaller than a pitch between each signal wire among the plurality of first signal wires, the plurality of second signal wires, and the plurality of third signal wires and a different signal wire adjacent to each signal wire in a vertical direction.

5. The semiconductor structure of claim 1, wherein
each signal wire among the plurality of first signal wires, the plurality of second signal wires, and the plurality of third signal wires, and each ground wire among the plurality of first ground wires, the plurality of second ground wires, and the plurality of third ground wires include an elongated shape.

6. The semiconductor structure of claim 1, further comprising
a fourth routing layer including a plurality of fourth signal wires and a plurality of fourth ground wires that are alternately arranged in the first horizontal direction and disposed on the third routing layer,
wherein the plurality of vias also connect the plurality of third ground wires and the plurality of fourth ground wires to each other,
wherein the plurality of fourth signal wires and the plurality of fourth ground wires extend in a second horizontal direction intersecting the first horizontal direction,
wherein each signal wire among the plurality of first signal wires, the plurality of second signal wires, the plurality of third signal wires, and the plurality of fourth signal wires is separated from remaining signal wires,
wherein the plurality of first signal wires, the plurality of second signal wires, the plurality of third signal wires, and the plurality of fourth signal wires overlap each other, and
wherein the plurality of first ground wires, the plurality of second ground wires, the plurality of third ground wires, and the plurality of fourth ground wires overlap each other.

7. The semiconductor structure of claim 1, further comprising
a fourth routing layer, or a fourth routing layer to an (N+4)^{th} routing layer, where N is a natural number of 1 or more,
wherein the fourth routing layer, or each of the fourth to (N+4)^{th} routing layers, includes a plurality of signal wires and a plurality of ground wires that are arranged alternately in the first horizontal direction.

8. A semiconductor structure comprising:
a first routing layer including a plurality of first signal wires and a plurality of first ground wires that are arranged alternately in a first horizontal direction;
a first connection layer including a plurality of first vias connected to the plurality of first ground wires and disposed on the first routing layer;
a second routing layer including a plurality of second signal wires and a plurality of second ground wires that are alternately arranged in the first horizontal direction and disposed on the first connection layer, wherein the plurality of second ground wires are connected to the plurality of first vias;
a second connection layer including a plurality of second vias connected to the plurality of second ground wires and disposed on the second routing layer;
a third routing layer including a plurality of third signal wires and a plurality of third ground wires that are alternately arranged in the first horizontal direction and disposed on the second connection layer, wherein the plurality of third ground wires are connected to the plurality of second vias; and
a dielectric surrounding the plurality of first signal wires, the plurality of second signal wires, and the plurality of third signal wires, the plurality of first ground wires, the plurality of second ground wires, and the plurality of third ground wires, and the plurality of first vias and the plurality of second vias,
wherein the plurality of first signal wires, the plurality of second signal wires, the plurality of third signal wires, the plurality of first ground wires, the plurality of second ground wires, and the plurality of third ground wires extend in a second horizontal direction intersecting the first horizontal direction,
wherein each signal wire among the plurality of first signal wires, the plurality of second signal wires, and the plurality of third signal wires is separated from remaining signal wires,
wherein the plurality of first signal wires, the plurality of second signal wires, and the plurality of third signal wires overlap each other, and
wherein the plurality of first ground wires, the plurality of second ground wires, and the plurality of third ground wires overlap each other.

9. The semiconductor structure of claim 8, wherein
the semiconductor structure includes a silicon interposer.

10. The semiconductor structure of claim 8, wherein
the semiconductor structure includes a redistribution layer structure.

11. The semiconductor structure of claim 8, wherein
a pitch between each signal wire among the plurality of first signal wires, the plurality of second signal wires, and the plurality of third signal wires and a different signal wire adjacent to each signal wire in a vertical direction is in a range of 2 μm to 10 μm.

12. A semiconductor package comprising:
a substrate;
an interconnection structure on the substrate;
a semiconductor die on the interconnection structure; and
a semiconductor stacking structure on the interconnection structure,
wherein the interconnection structure includes:
a first routing layer including a plurality of first signal wires and a plurality of first ground wires that are arranged alternately in a first horizontal direction;
a second routing layer including a plurality of second signal wires and a plurality of second ground wires that are alternately arranged in the first horizontal direction and disposed on the first routing layer;
a third routing layer including a plurality of third signal wires and a plurality of third ground wires that are alternately arranged in the first horizontal direction and disposed on the second routing layer; and
a plurality of vias connecting the plurality of first ground wires, the plurality of second ground wires, and the plurality of third ground wires to each other,
wherein the plurality of first signal wires, the plurality of second signal wires, and the plurality of third signal wires, the plurality of first ground wires, the plurality of second ground wires, and the plurality of third ground wires extend in a second horizontal direction intersecting the first horizontal direction,
wherein each signal wire among the plurality of first signal wires, the plurality of second signal wires, and the plurality of third signal wires is separated from remaining signal wires,
wherein the plurality of first signal wires, the plurality of second signal wires, and the plurality of third signal wires overlap each other, and
wherein the plurality of first ground wires, the plurality of second ground wires, and the plurality of third ground wires overlap each other.

13. The semiconductor package of claim 12, wherein
an upper surface of the substrate contacts a lower surface of the interconnection structure.

14. The semiconductor package of claim 12, wherein
each signal wire among the plurality of first signal wires, the plurality of second signal wires, and the plurality of third signal wires is electrically connected to at least one of the semiconductor die or the semiconductor stacking structure.

15. The semiconductor package of claim 12, wherein
each signal wire among the plurality of first signal wires, the plurality of second signal wires, and the plurality of third signal wires is electrically connected to the substrate.

16. The semiconductor package of claim 12, wherein
the plurality of first ground wires, the plurality of second ground wires, and the plurality of third ground wires are electrically connected to the semiconductor die or the semiconductor stacking structure.

17. The semiconductor package of claim 12, wherein
the plurality of first ground wires, the plurality of second ground wires, and the plurality of third ground wires are electrically connected to the substrate.

18. The semiconductor package of claim 12, wherein
the semiconductor die includes a system on a chip (SoC).

19. The semiconductor package of claim 12, wherein
the semiconductor stacking structure includes a high bandwidth memory (HBM).

20. The semiconductor package of claim 12, wherein
the substrate includes a printed circuit board (PCB).
